(19) United States
(12) Patent Application Publication
(10) Pub. No.: US 2025/0006646 A1
(43) Pub. Date: Jan. 2, 2025

(54) THROUGH GLASS VIAS WITH COMPLIANT LAYER FOR INTEGRATED CIRCUIT DEVICE PACKAGES

(71) Applicant: Intel Corporation, Santa Clara, CA (US)

(72) Inventors: Xing Sun, Chandler, AZ (US); Srinivas Pietambaram, Chandler, AZ (US); Darko Grujicic, Chandler, AZ (US); Rengarajan Shanmugam, Tempe, AZ (US); Brian Balch, Chandler, AZ (US); Micah Armstrong, Scottsdale, AZ (US); Qiang Li, Chandler, AZ (US); Marcel Wall, Phoenix, AZ (US); Rahul Manepalli, Chandler, AZ (US)

(73) Assignee: Intel Corporation, Santa Clara, CA (US)

(21) Appl. No.: 18/216,525

(22) Filed: Jun. 29, 2023

(51) Int. Cl. H01L 23/538; H01L 21/48; H01L 23/00; H01L 23/15; H01L 25/065

(52) U.S. Cl. CPC H01L 23/5384; H01L 21/486; H01L 23/15; H01L 23/5383; H01L 24/08; H01L 24/16; H01L 25/0655; H01L 2224/08225; H01L 2224/16225

(57) ABSTRACT

Integrated circuit (IC) die packages including a glass with conductive through-glass vias (TGVs). The TGVs are lined with a buffer comprising an inorganic material having a low elastic (Young's) modulus. The buffer may thereby accommodate internal stress between the glass and through via metallization formed over the buffer. The compliant inorganic material may be a metal or metal alloy, for example, different than that of the via metallization. The inorganic material may also be a metal nitride, metal silicide, or metal carbide. A TGV buffer may be one material layer of a stack comprising two or more material layers deposited upon TGV sidewall surfaces. A routing structure may be built-up on at least one side of the glass and IC die assembled to the routing structure. The buffer Ipresent within the TGVs may be absent from metal features of the routing structure.

### BACKGROUND

In electronics manufacturing, IC packaging is a stage of semiconductor device fabrication in which an IC that has been monolithically fabricated on a chip (or die) is assembled into a “package” that can protect the IC chip from physical damage and communicatively connect the IC to other packaged IC chips and/or a scaled host component, such as a package substrate, or a printed circuit board. Multiple chips can be co-assembled, for example, into a multi-die package (MCP).

Some multi-die package architectures may include IC die attached to a glass substrate and coupled to electrically conductive through-glass vias (TGVs) extending through the glass substrate. However, a glass substrate has a significantly lower CTE than conventional organic copper-cored/coreless substrates. As such, metal within TGVs can suffer high internal stress potentially resulting in mechanical failures during reliability testing, and reducing device package yields.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a flow diagram of methods for forming an IC device package structure including IC die coupled to a glass preform comprising through-glass vias (TGVs) lined with a buffer comprising an inorganic material layer, in accordance with some embodiments;

FIGS. 2A, 2B and 2C illustrate cross-sectional views of an IC device package structure evolving to include a compliant buffer lining TGV openings as selected operations in the methods illustrated in FIG. 1 are performed, in accordance with some embodiments;

FIGS. 3, 4, and 5 illustrate expand cross-section views of an inorganic material layer within a multi-layer buffer of a TGV opening, in accordance with some embodiments;

FIGS. 6A and 6B illustrate cross-sectional views of an IC device package structure evolving to include TGVs with a compliant buffer including an inorganic material layer as selected operations in the methods illustrated in FIG. 1 are performed, in accordance with some embodiments;

FIGS. 7A, 7B and 7C illustrate cross-sectional views of an IC device package structure evolving to include multiple IC dies interconnected by an electrical routing structure built up on a side of a glass that includes TGVs with a compliant buffer as selected operations in the methods illustrated in FIG. 1 are performed, in accordance with some embodiments;

FIG. 8 illustrates a system including the IC device package structure illustrated in FIG. 7C attached to a host component with solder features, in accordance with some embodiments;

FIG. 9 illustrates a mobile computing platform and a data server machine employing device package structures comprising TGVs with a compliant buffer including an inorganic material, in accordance with some embodiments; and

FIG. 10 is a functional block diagram of an electronic computing device, in accordance with some embodiments.

### DETAILED DESCRIPTION OF EXEMPLARY EMBODIMENTS

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

Integrated circuit (IC) device package structures including a glass with conductive through-glass vias (TGVs) are described herein. In exemplary embodiments, the TGVs are lined with a compliant inorganic material having a significantly lower elastic (Young's) modulus than via metallization deposited over the inorganic material. The greater compliance of the inorganic material may accommodate internal stress that develops between the glass and via metallization that is deposited into the TGVs (e.g., covering the buffer). In exemplary embodiments, the inorganic material has an elastic modulus of less than 110 GPa while via metallization (e.g., predominantly copper), may have an elastic modulus of at least 125 GPa. Compliant inorganic material described herein are generally thin films. While in some instances the modulus may be directly measured for a thin film, references to elastic modulus are also applicable for bulk materials having substantially the same chemical composition and microstructure as the thin film. Hence, even if elastic modulus of a particular thin film is not readily measurable, a material of substantially the same composition and microstructure may be formed to some bulk thickness more amenable to modulus measurement. Absent evidence to the contrary, the modulus associated with such a bulk thickness is presumed to be closely correlated with that of a thin film of substantially the same composition and microstructure.

In some advantageous embodiments, the inorganic material has a low CTE (e.g., <20 ppm/K) compatible with the CTE of silica glass (e.g., 4-9 ppm/K). In some exemplary embodiments, the inorganic material has a lower CTE than via metallization that is deposited into the TGVs. As described further below, the inorganic material may be a metal or metal alloy, for example, different than that of the via metallization. The inorganic material may also be a metallic compound. A TGV buffer in accordance with embodiments may be a single material layer or a stack of materials including at least one other material layer lining sidewall surfaces of through holes formed in the glass. While in some instances the CTE may be directly measured for the thin film implementations described herein, references to CTE are also applicable for bulk materials having substantially the same chemical composition and microstructure as the thin film. Hence, even if CTE of a particular thin film is not readily measurable, a material of substantially the same composition and microstructure may be formed to some bulk thickness more amenable to CTE measurement. Absent evidence to the contrary, the CTE associated with such a bulk thickness is presumed to be closely correlated with that of a thin film of substantially the same composition and microstructure.

An electrical routing structure comprising redistribution layer (RDL) metallization may be built-up on at least one side of the glass, and IC die(s) assembled to the routing structure. The buffer present within the TGVs may be absent from metal features of the routing structure.

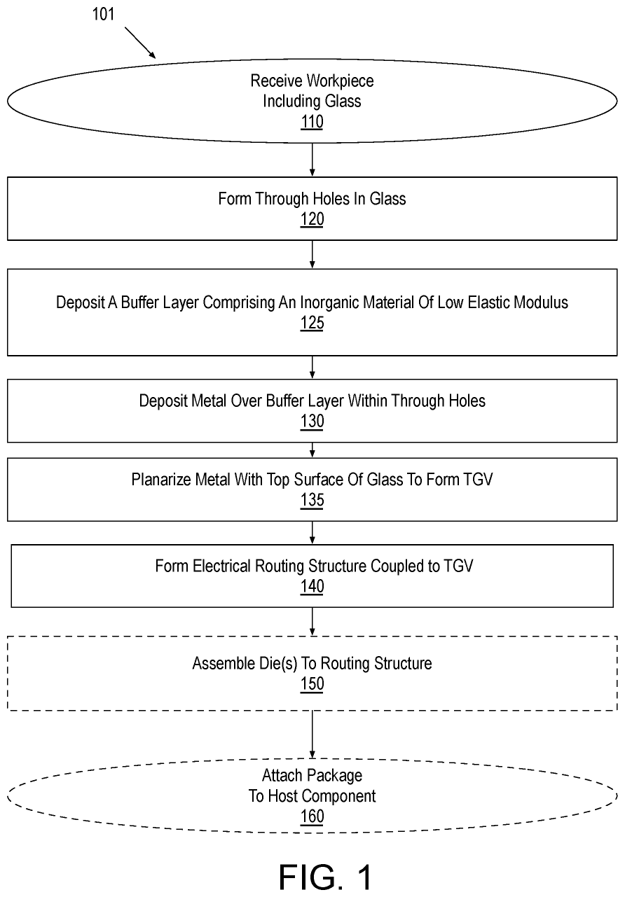

A variety of fabrication methods may be practiced to form IC device package structures having one or more of the features described herein. FIG. 1 illustrates a flow diagram of methods 101 for forming an IC device package structure including IC die coupled to a bulk glass layer comprising through-glass vias (TGVs) lined with a compliant buffer, in accordance with some embodiments. Methods 101 begin at input 110 where a workpiece including a thickness of glass is received. The workpiece may be prepared upstream of methods 101 and may be in a large panel format, a wafer format, or the like. In addition to the glass, the workpiece received at input 110 may comprise one or more materials upon which electrical routing structures may be formed.

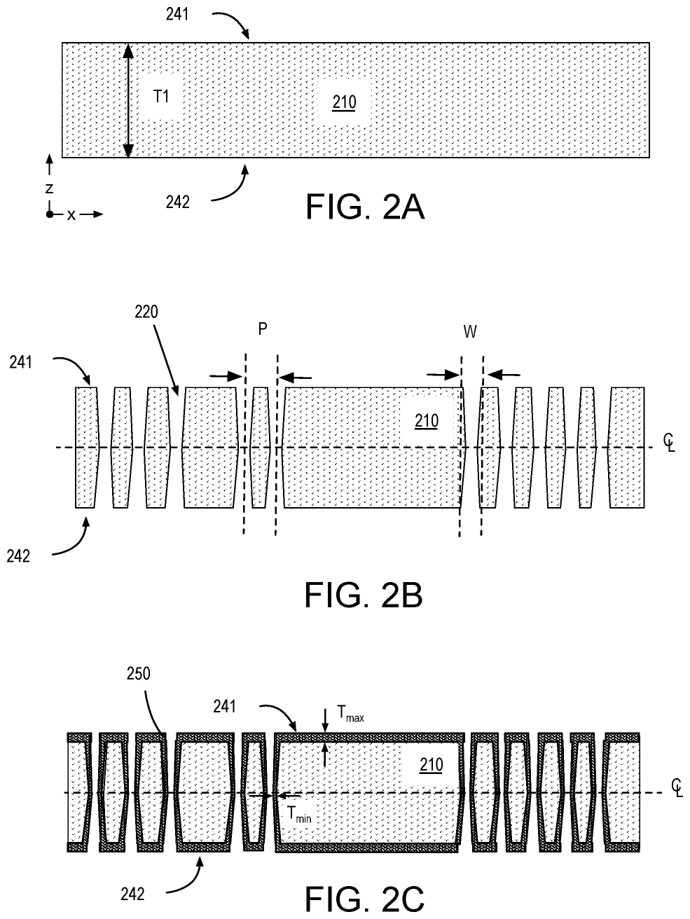

FIG. 2A is a cross-sectional view of an exemplary workpiece including glass 210. IC device package structures may be advantageously fabricated upon such a glass as flatness and/or thickness control for a preform of glass is superior to that of starting substrates based on organic materials (e.g., epoxy), and costs can be significantly lower than for monocrystalline materials (e.g., silicon). Glass 210 is a solid bulk material layer that may have been previously formed into any shape in plan view (e.g., x-y plane) suitable for a packaging workpiece, such as rectangular. Glass 210 has a thickness T1 that may vary with implementation, for example to limit warpage while remaining thin enough to permit the formation of through vias at a pitch as small as is enabled by the surface flatness of glass 210. In exemplary embodiments, thickness T1 is advantageously 200 μm to 2000 μm.

Glass 210 is advantageously predominantly silicon and oxygen. In some embodiments, glass 210 comprises at least 23 percent silicon and at least 26 percent oxygen, by weight (i.e., wt. %). Glass 210 may further include one or more additives, such as, Aluminum, Boron, Magnesium, Calcium, Barium, Tin, Sodium, Potassium, Strontium, Phosphorus, Zirconium, Lithium, Titanium, or Zinc. In some embodiments where glass 210 comprises at least 23 wt. % Si and at least 26 wt. % O, glass 210 further comprises at least 5 wt. % Al. Additives within glass 210 may form suboxides (A₂O) monoxides (AO), binary oxides (AO₂), ternary oxides (ABO₃), and mixtures thereof. For example, glass 210 may comprise AlOₓ (e.g., Al₂O₃), BOₓ (e.g., B₂O₃), MgOₓ (e.g., MgO), CaOₓ (e.g., CaO), SrOₓ (e.g., SrO), BaOₓ (e.g., BaO), SnOₓ (e.g., SnO₂), NaOₓ (e.g., Na₂O), KOₓ (e.g., K₂O), POₓ (e.g., P₂O₃), ZrOₓ (e.g., ZrO₂), LiOₓ (e.g., Li₂O), TiOₓ (e.g., TiO₂), or ZnOₓ (e.g., ZnO₂). Depending on chemical composition, glass 210 may therefore be referred to as silica, fused silica, aluminosilicate, borosilicate, or alumino-borosilicate, for example.

Glass 210 is advantageously a bulk material of substantially homogeneous composition in contrast to a composite material that may merely comprise glass fillers and/or fibers. Although glass 210 is substantially amorphous in some embodiments, glass 210 may also have other morphology or microstructure, such as polycrystalline (e.g., nanocrystalline).

Although not depicted, one or more material layers may clad either or both of the front-side surface 241 or back-side surface 242 of glass 210 so that glass 210 is a bulk or core layer of a multi-layered substrate. Exemplary cladding materials include inorganic materials such as silicon nitride (SiNₓ) or silicon oxynitride (SiOₓN_{y}). In other embodiments, a silicon layer (polycrystalline or monocrystalline) may clad one or both sides of glass 210. Organic material layers, such as polymer dielectric materials, may also clad one or more sides of glass 210. Hence, while glass 210 is advantageously substantially free of organic materials (e.g., no adhesives, etc.), a workpiece may include organic within a substrate stack that includes glass 210.

Returning to FIG. 1, methods 101 continue at block 120 where features (e.g., through holes) are formed in the glass. The features may be fabricated with any process known to be suitable for bulk glass. In some embodiments, block 120 entails for laser ablation, a glass etch process (laser-assisted, or otherwise), or any other technique known to be suitable for forming features (e.g., holes) through a thickness of the glass received at input 110 at a desired diameter and feature pitch.

FIG. 2B illustrates an exemplary embodiment indicative of a substantially symmetrical two-sided hole formation process resulting in through holes 220 that are substantially symmetric about a longitudinal z-axis (demarked in dashed line) but with a tapered (e.g., x dimension) lateral width W that is largest at each of a front-side surface 241 and a back-side surface 242 of glass 210. Through holes 220 have a smallest lateral width W proximal to one-half of thickness T1 or a centerline plane of glass 210. The largest width W may vary with implementation. However, in some examples the largest width W is 100 μm, or less, and advantageously 50 μm, or less. Accordingly, the aspect ratio (T1: largest width W) of through holes 220 may also vary with an exemplary range being 4-20. In some embodiments where glass 210 has a thickness T1 of at least 500 μm, through holes 220 have a minimum lateral pitch P that is 200 μm, or less, and advantageously 100 μm, or less. Although the symmetrical taper illustrated in FIG. 2B is indicative of a two-sided through-hole formation process, single-sided asymmetrical though hole embodiments are also possible. Also, although only through holes are illustrated in FIG. 2B, blind holes or recesses that do not pass entirely through thickness T1 may also be fabricated into one or more of front-side surface 241 or back-side surface 242. Through holes 220 may have any shape within a plan view (x-y) plane, such as substantially circular, rectangular, or any other polygon. The plan view shape may vary over thickness T1.

Returning to FIG. 1, methods 101 continue at block 125 where a compliant buffer is deposited as a liner upon sidewalls of the features formed into a bulk glass. The buffer includes a sufficiently compliant material (i.e., of sufficiently low elastic modulus) to accommodate internal stress between the glass land metallization subsequently deposited in the features. The magnitude of stress developed may vary with implementation, for example as a function of feature geometry and thermal stress. FIG. 2C illustrates an exemplary through hole via buffer 250 that has been deposited upon surfaces of glass 210.

In exemplary embodiments, through hole via buffer 250 comprises an inorganic material and may advantageously be entirely of inorganic material. In contrast to organic materials that can be difficult to deposit in a manner that ensures side walls of the through holes are fully covered, inorganic materials in accordance with embodiments herein can be readily deposited (e.g., by physical vapor deposition (PVD), chemical vapor deposition (CVD) or atomic layer deposition (ALD)). The example illustrated in FIG. 2C is indicative of a double-side PVD process that deposits buffer 250 to a maximum thickness Tₘₐₓ on front side and back side surfaces 241, 242 and to a minimum thickness Tₘᵢₙ proximal to the glass centerline at one-half of thickness T1.

Although buffer thicknesses may vary with implementation, in exemplary embodiments minimum thickness Tₘᵢₙ is at least 50 nm. Depending on properties of the buffer, maximum thickness Tₘₐₓ may be advantageously less than 350 nm. A limitation on maximum thickness Tₘₐₓ may, for example, limit the impact of buffer 250 on a through via's electrical resistance. Maximum thickness Tₘₐₓ may, for example, be less for embodiments where buffer 250 has higher electrical resistance and allowed to be greater for embodiments where buffer 250 has lower electrical resistance.

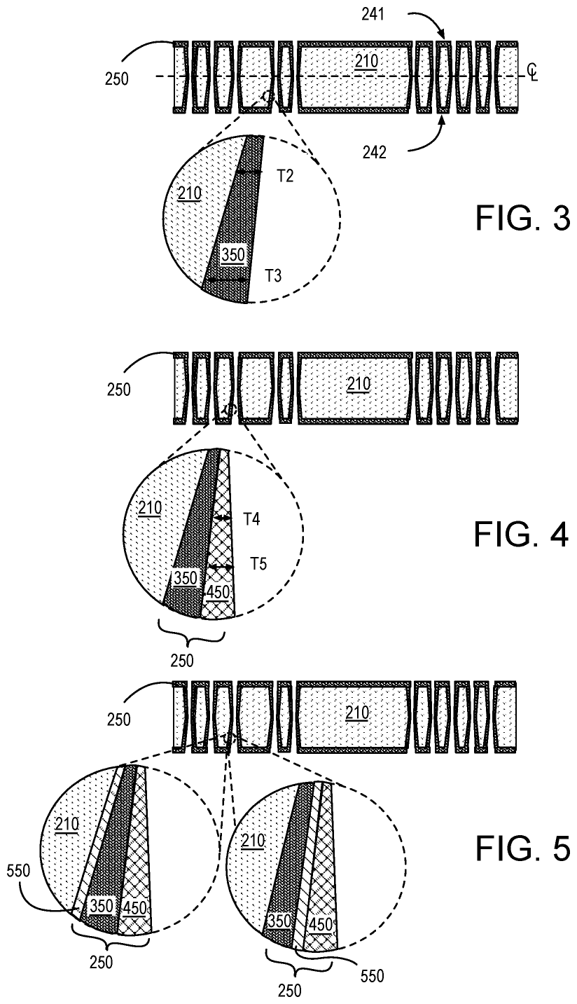

As further illustrated in FIG. 3, through hole via buffer 250 may be a single layer of inorganic material 350 in direct contact with a sidewall surface of glass 210. In the illustrated example, inorganic material layer 350 has a lower thickness T2 proximal to the glass centerline and a greater thickness T3 proximal to front-side and back-side surface 241, 242. This variation in thickness is indicative of a non-conformal deposition process, such as PVD.

In exemplary embodiments, inorganic material 350 has an elastic modulus less than 110 GPa. The inventors have found materials (e.g., most copper metallization) with an elastic modulus significantly above this threshold (e.g., 120 GPa) may not accommodate as much internal stress. When deposited within a hole extending through a low-CTE material (e.g., glass), the less compliant material(s) may suffer delamination. Some embodiments of inorganic material 350 may therefore have an even lower elastic modulus (e.g., advantageously below 100 GPa, and more advantageously below 90 GPa).

Inorganic materials in accordance with embodiments herein also have a (linear) coefficient of thermal expansion (CTE) suitable for a bulk glass. In exemplary embodiments where glass 210 has a CTE of 4-9 ppm/K, the CTE of inorganic material layer 350 is less than 25 ppm/K. In embodiments where inorganic material layer 350 is a compliant inorganic material (i.e., <110 GPa), inorganic material layer 350 also has a CTE below 25 ppm/K. In some exemplary embodiments inorganic material layer 350 has a CTE below that of an overlying metallization. Inorganic material layer 350 may advantageously have a CTE in the range of 3-20 ppm/K, and more advantageously in the range 4-15 ppm/K.

In some exemplary embodiments, inorganic material layer 350 comprises one or more metals and may be predominantly metal. In some embodiments, inorganic material layer 350 is a substantially pure metal and in some other embodiments, inorganic material layer 350 is a metal alloy. Several metals have an elastic modulus below 110 GPa, and a subset of those additionally have a CTE below 25 ppm/K. Exemplary metals include Al, Sn, Sc, In, Au and Ag, which all have an elastic modulus below 80 GPa and a CTE below 25 ppm/K. Other metals having a similarly low elastic modulus and CTE may also be suitable.

In some embodiments where inorganic material layer 350 comprises an alloy of two or more metals, at least one metal has a bulk elastic modulus below 110 GPa, and at least one metal has a bulk CTE below 25 ppm/K. Alloys of metals of low elastic modulus and/or low CTE may be tuned through their factional composition to optimize the combination of low modulus and low CTE for the alloy. For example, in one embodiment inorganic material layer 350 may be substantially pure Al (e.g., ε of ˜70 GPa and CTE of 21-24 ppm/K). In other embodiments, inorganic material layer 350 may be an alloy of Al (e.g., Ti—Al), which can be compositionally tuned to a lower CTE (e.g., 9-15 ppm/K) well below that of substantially pure Al while still maintaining a CTE (e.g., 110-115) well below that of substantially pure Ti.

Suitable metal alloys may be a binary alloy, for example including at least one of Al, Sn, Sc, In, Au, or Ag. The binary alloy may further comprise two of Al, Sn, Sc, In, or Ti (e.g., Au—Sn, Al—Ti, Al—Sc, Al—In, etc.). Metal alloys suitable as inorganic material layer 350 may also be ternary alloys or quaternary alloys, etc. In still other embodiments, inorganic material layer 350 is a metallic compound such as, a metal carbide (e.g., AlC), or a metal silicide (e.g., Al—Si, Al—Ti—Si). Metal nitrides with an elastic modulus below 110 GPa may also be suitable as inorganic material layer 350.

In alternative embodiments, inorganic material layer 350 is a non-metal, such as substantially pure silicon (e.g., with an elastic modulus of 47-80 and a CTE of around 3 ppm/K) or diamond-like carbon (DLC), which depending on the process(es) employed in its formation, may have an elastic modulus as low as 90-100 GPa and a CTE of 3-6 ppm/K.

Some though hole via buffer embodiments may incorporate an inorganic material layer into a multi-layered stack of materials. For embodiments where the inorganic material layer has good adhesion to glass, the inorganic material layer is in direct contact with a sidewall of glass, and one or more other thin film material layers may be deposited over the inorganic material layer. Material layers deposited over the inorganic material layer may be advantageous, for example, where the inorganic material is not suitable for the subsequent deposition of via metallization. In the embodiments illustrated in FIG. 4, through hole via buffer 250 comprises inorganic material layer 350 between a sidewall of glass 210 and a metal seed layer 450. In the illustrated embodiment, inorganic material layer 350 is in direct contact with both glass 210 and seed layer 450.

Inorganic material layer 350 may have any of the chemical compositions, material properties, and thicknesses described above. Metal seed layer 450 may be of any chemical composition known to be suitable as a seed layer for an electrodeposition process, for example having suitable electrical conductivity. Metal seed layer 450 may be predominantly Cu, for example. For embodiments where inorganic material layer 350 comprises predominantly Al, an Al—Cu intermetallic phase may form at the interface of metal seed layer 450, ensuring good adhesion of metal seed layer 450. In the illustrated embodiment, metal seed layer 450 has a lower thickness T4 proximal to the glass centerline and a greater thickness T5 proximal to front-side and back-side surface 241, 242. This variation in thickness is indicative of a non-conformal deposition process, such as PVD. For embodiments shown in FIG. 4, inorganic material layer 350 may have other chemical compositions not possible for embodiments shown in FIG. 3 where inorganic material layer 350 is also to function as a seed layer.

For other examples where an inorganic material layer is incorporated into a multi-layer stack of materials, the inorganic material layer may be separated from a sidewall of a bulk glass by one or more other thin film material layers and/or the inorganic material layer may be separated from a seed layer by one or more other thin film material layers. Such embodiments may be advantageous where the inorganic material does not have good adhesion with glass and/or a seed layer, for example. In one embodiment illustrated in FIG. 5, through hole via buffer 250 is a multi-layered stack that includes inorganic material layer 350 between an adhesion layer 550 and seed layer 450. Inorganic material layer 350 and seed layer 450 may have any of the chemical compositions, material properties, and thicknesses described above. Adhesion layer 550 may have another composition, such as Ti, TiN, for example. Although adhesion layer 550 may have any thickness, in exemplary embodiments adhesion layer 550 has a thickness significantly less than that of inorganic material layer 350.

In another example illustrated in FIG. 5, through hole via buffer 250 is a multi-layered stack that includes adhesion layer 550 between inorganic material layer 350 and seed layer 450. Inorganic material layer 350, seed layer 450, and adhesion layer 550 may have any of the chemical compositions, material properties, and thicknesses described above. Other material layers may also be included in a through hole buffer. For example, in some embodiments a magnetic material is under or over inorganic material layer 350 within a buffer that is advantageous for inductor cores.

Returning to FIG. 1, methods 101 continue at block 130 where a suitable metal is deposited within the through holes to form electrically conductive through vias, which may be referred to as through substrate vias (TSVs) or more particularly through glass vias (TGVs). The via metallization is then planarized at block 135 to remove overburden associated with the plating process and/or remove the through hole buffer from front and back sides of the glass.

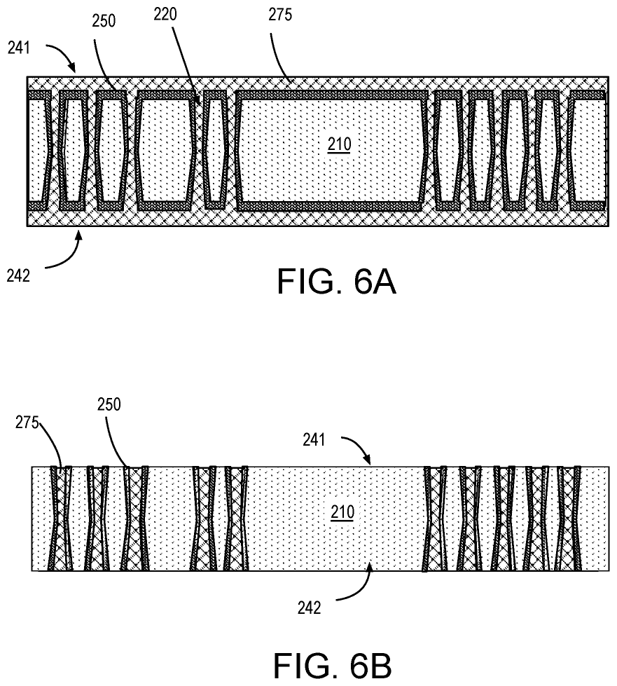

In the example further illustrated in FIG. 6A, a via metallization 275 has been deposited over front-side and back-side surfaces 241, 242, as well as into through holes 220. Via metallization 275 is in direct contact with through hole buffer 250 and may, but need not, substantially fill through holes 220. In some examples, via metallization 275 is one or more metals (e.g., predominantly copper) deposited (e.g., electroplated) upon surfaces of the workpiece covered by the through hole buffer. Via metallization 275 may have a significantly higher elastic modulus and/or CTE than inorganic material layer 350. Via metallization of predominantly Cu, for example, can be expected to have an elastic moduls of around 130 GPa and a CTE of 16-17 ppm/K. FIG. 6B further illustrates a workpiece after planarization of front-side and back-side surfaces 241, 242. As shown, following planarization, via metallization 275 and through hole buffer 250 remains only adjacent to sidewalls of glass 210. Workpiece in FIG. 6B can also be obtained by chemical metal etch processes without incorporating mechanical abrasion in planarization.

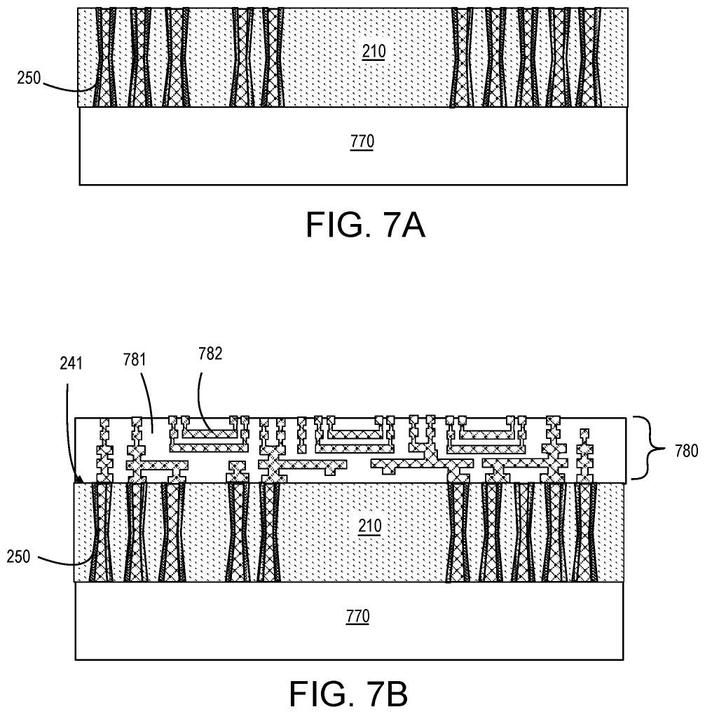

After the formation of conductive through vias, glass 210 may be affixed to a handle or carrier 770, as further depicted in FIG. 7A. Carrier 770 may have any suitable composition and be of any suitable thickness, as embodiments herein are not limited in this context.

Returning to FIG. 1, methods 101 continue at block 140 where an electrical routing structure is built up over at least one side of the glass prior to assembly with IC die. The electrical routing structure may be electrically coupled to the through vias and may, for example, comprise one or more levels of metallization features embedded within any suitable dielectric material. The electrical routing structure formed at block 140 may interconnect one or more IC die to each other and/or couple one or more of IC die to the conductive through vias. Accordingly, the metallization feature pitch of the routing structure is advantageously minimized for highest interconnect density.

In the example illustrated in FIG. 7B, a routing structure 780 has been built-up over front-side surface 241. Routing structure 780 comprises one or more levels of RDL metallization features 782 embedded within one or more layers of dielectric material 781. RDL metallization features 782 may comprise one or more metals, with one example being predominantly copper. At least some of RDL metallization features 782 are to electrically bridge together two or more IC dies, preferably with the finest metallization line: space feature pitch that can be directly patterned (e.g., <3 μm lines and spaces) as enabled by the improved flatness profile of glass 210 compared to traditional organic preform cores. Routing structure 780 further comprises metallization features 782 that are to interconnect multiple IC dies to conductive TGVs. In some examples where the TGVs comprise a compliant buffer 250 that includes an inorganic material layer in accordance with embodiments herein, the inorganic material layer is absent from metallization features 782.

Depending on the embodiment, dielectric material 781 may be any of a molding compound, a spin-on material, or dry film laminate material, for example. Dielectric material 781 may be introduced wet/uncured into a cast and then dried/cured. Alternatively, dielectric material 781 may be introduced as a semi-cured dry film that is fully cured following its application to glass 210.

The composition of dielectric material 781 may vary with implementation. In some advantageous embodiments, dielectric material 781 is an organic dielectric, such as, an epoxy resin, phenolic-glass, or a resinous film such as the GX-series films commercially available from Ajinomoto Fine-Techno Co., Inc. (ABF). Dielectric material 781 may comprise epoxy resins (e.g., an acrylate of novolac such as epoxy phenol novolacs (EPN) or epoxy cresol novolacs (ECN)). In some specific examples, dielectric material 781 is a bisphenol-A epoxy resin, for example including epichlorohydrin. In other examples, dielectric material 781 includes aliphatic epoxy resin.

Returning to FIG. 1, methods 101 continue at block 150 where at least one IC die is assembled to the workpiece and, more particularly, to the electrical routing structure that was formed at block 140. IC die assembled at block 150 may each comprise any electrical circuitry, with one example being logic circuitry comprising logic gates. IC die assembled at block 150 may also comprise any photonic circuitry suitable for the detection, emission or processing (e.g., filtering, multiplexing and demultiplexing) of optical signals.

In the example illustrated in FIG. 7C, IC die 791-794 are assembled to interconnect interfaces within a top metallization level of routing structure 780 as the first die of a co-packaged multi-die IC device package structure 701. IC die 791-794 may be directly bonded to routing structure 780, or, electrically coupled through intervening electrical interconnects 785, which may comprise solder of any suitable composition. In the example illustrated, IC die 791-793 are each flip-chip attached with integrated circuitry within each die being proximal to front-side surface 241. IC die 794 however comprises through die vias 799 with integrated circuitry being distal from front-side surface 241.

Each of IC die 791-794 may be a fully functional ASIC, or may be a chiplet or tile that has more limited functionality supplementing the function of one or more other IC dies that are to be part of the same multi-die device. A chiplet or tile may, for example, be any of a wireless radio circuit, microprocessor core, electronic memory circuit, floating point gate array (FPGA), power management and/or power supply circuit, or include a MEMS device. In some examples, one or more of IC die 791-794 include one or more banks of active repeater circuitry to improve multi-die interconnects (e.g., network-on-chip architectures). In other examples, one or more of IC die 791-794 includes clock generator circuitry or temperature sensing circuitry. In other examples, one or more of IC die 791-794 include logic circuitry that, along with other IC die 791-794 implement multi-chiplet aggregated logic circuitry (e.g., mesh network-on-chip architectures). In some specific examples, at least one of IC die 791-794 includes microprocessor core circuitry, for example comprising one or more shift registers.

IC die 791-794 advantageously comprise field effect transistors (FETs) with a device pitch of 80 nm, or less. The FETs may be of any architecture (e.g., planar, non-planar, single-gate, multi-gate, stacked nanosheet, etc.). In some embodiments, FET terminals have a feature pitch of 20-40 nm. Additionally, or in the alternative, IC die 791-794 may include active devices other than FETs. For example, IC die 791-794 may include electronic memory structures, such as magnetic tunnel junctions (MTJs), capacitors, or the like.

IC die 791-794 may comprise one or more IC die metallization levels embedded within an insulator. While the IC die metallization features may have any composition(s) of sufficient electrical conductivity, in exemplary embodiments, the IC die metallization features are predominantly copper (Cu). In other examples, the metallization features are predominantly other than Cu, such as, but not limited to predominantly Ru, or predominantly W. An uppermost one of the metallization features within IC die 791-794 may have a feature pitch ranging from 100 nm to several microns, for example.

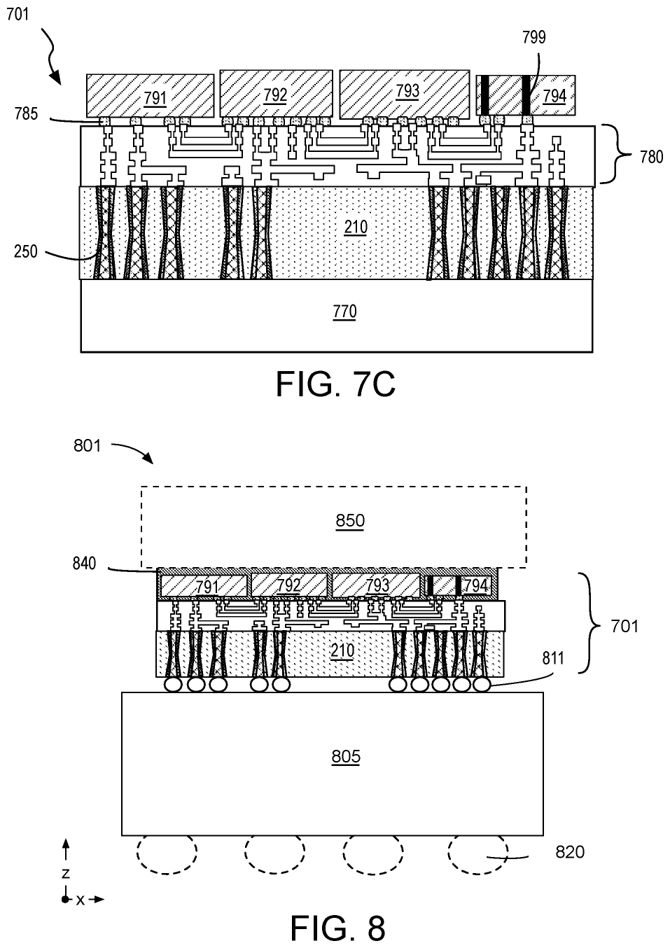

Returning to FIG. 1, methods 101 complete at output 160 where the assemble device package structure is attached to any suitable host component. FIG. 8 illustrates an exemplary system 801 including one device package structure 701 attached to a host component 805 with interconnects 811, in accordance with some embodiments. In exemplary embodiments, interconnects 811 are solder (e.g., SAC) microbumps although other interconnect features are also possible. In some embodiments, host component 805 is predominantly silicon. Host component 805 may also comprise one or more alternative materials known to be suitable as interposers or package substrates (e.g., an epoxy preform, cored or coreless laminate board, etc.). Host component 805 may also include a printed circuit board (PCB). Host component 805 may include one or more metallized redistribution levels (not depicted) embedded within a dielectric material. Host component 805 may also include one or more IC die embedded therein.

Host component 805 may include interconnects 820 illustrated in dashed line. Interconnect 820 may comprise any solder (ball, bump, etc.) suitable for a given host board architecture (e.g., surface mount FR4, etc.). Also illustrated in dashed line, one or more heat spreaders and/or heat sinks 850 may be further coupled to device package structure 701, which may be advantageous, for example, where IC dies 791-794 comprise one or more CPU cores or other circuitry of similar power density. Any package dielectric 840, such as a mold material, may surround sidewalls of IC dies 791-794. Although not illustrated, package dielectric 840 may be background so that heat spreader/sink 850 may be in closer contact with IC dies 791-794,

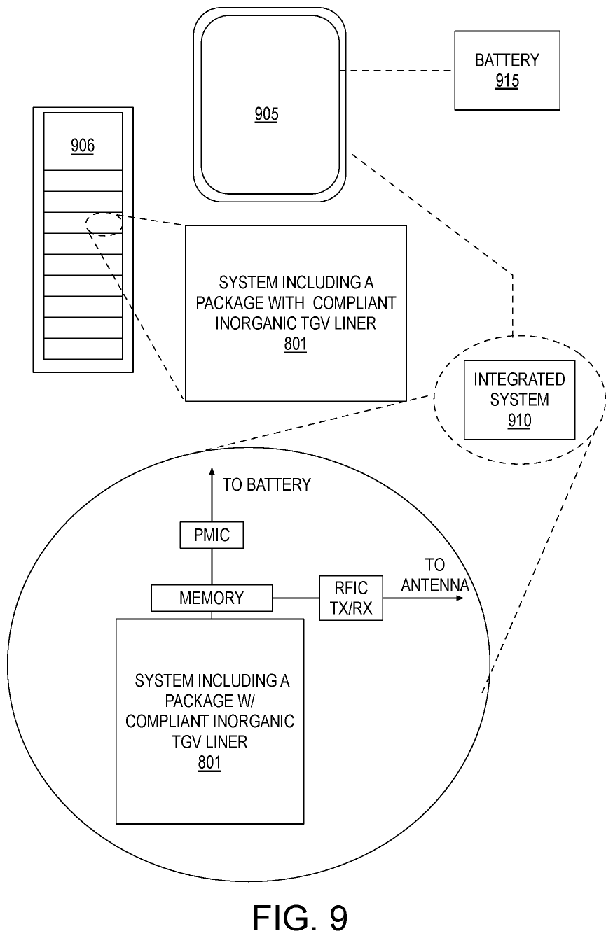

FIG. 9 illustrates a mobile computing platform 905 and a data server machine 906 employing an IC device package with TGVs including a low modulus inorganic material layer, for example as described elsewhere herein. Server machine 906 may be any commercial server, for example including any number of high-performance computing platforms disposed within a rack and networked together for electronic data processing, which in the exemplary embodiment includes system 801, for example as described elsewhere herein. The mobile computing platform 905 may be any portable device configured for each of electronic data display, electronic data processing, wireless electronic data transmission, or the like. For example, the mobile computing platform 905 may be any of a tablet, a smart phone, laptop computer, etc., and may include a display screen (e.g., a capacitive, inductive, resistive, or optical touchscreen), an integrated system 910, and a battery 915.

As illustrated in the expanded view, system 801 is coupled to one or more of a power management integrated circuit (PMIC) or RF (wireless) integrated circuit (RFIC) including a wideband RF (wireless) transmitter and/or receiver. A PMIC may perform battery power regulation, DC-to-DC conversion, etc., and so has an input coupled to battery 915 and with an output providing a current supply to other functional modules. As further illustrated, in the exemplary embodiment, an RFIC has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, and beyond.

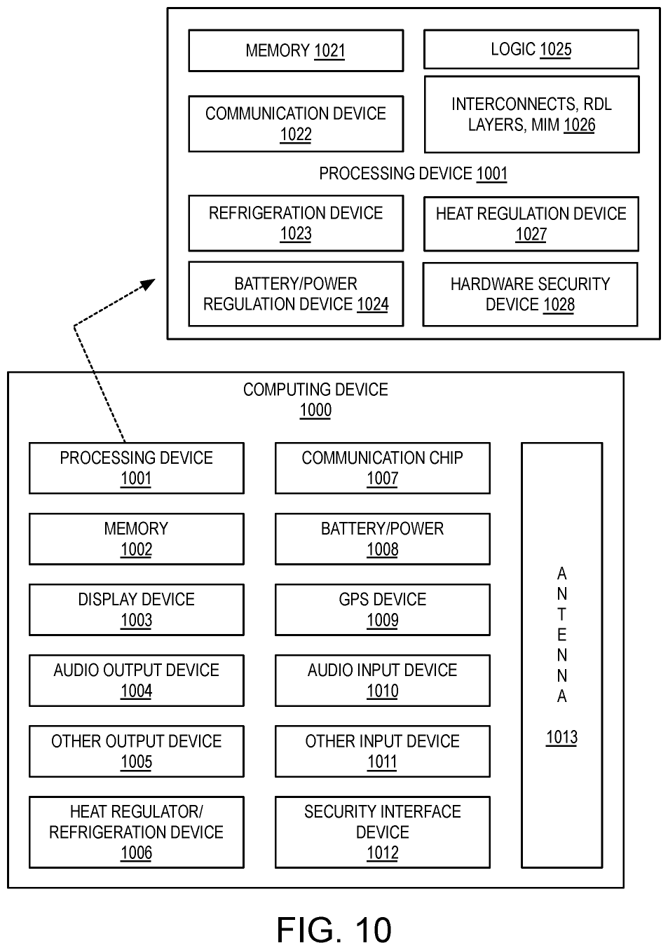

FIG. 10 is a block diagram of a cryogenically cooled computing device 1000 in accordance with some embodiments. For example, one or more components of computing device 1000 may include any of the devices or structures discussed elsewhere herein. A number of components are illustrated in FIG. 10 as included in computing device 1000, but any one or more of these components may be omitted or duplicated, as suitable for the application. In some embodiments, some or all of the components included in computing device 1000 may be attached to one or more printed circuit boards (e.g., a motherboard). In some embodiments, various ones of these components may be fabricated onto a single system-on-a-chip (SoC) die. Additionally, in various embodiments, computing device 1000 may not include one or more of the components illustrated in FIG. 10, but computing device 1000 may include interface circuitry for coupling to the one or more components. For example, computing device 1000 may not include a display device 1003, but may include display device interface circuitry (e.g., a connector and driver circuitry) to which display device 1003 may be coupled.

Computing device 1000 may include a processing device 1001 (e.g., one or more processing devices). As used herein, the term processing device or processor indicates a device that processes electronic data from registers and/or memory to transform that electronic data into other electronic data that may be stored in registers and/or memory. Processing device 1001 may include a memory 1021, a communication device 1022, a refrigeration/active cooling device 1023, a battery/power regulation device 1024, logic 1025, interconnects 1026, a heat regulation device 1027, and a hardware security device 1028.

Processing device 1001 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 1001 may include a memory 1002, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1021 includes memory that shares a die with processing device 1001. This memory may be used as cache memory and may include embedded dynamic random-access memory (eDRAM) or spin transfer torque magnetic random-access memory (STT-M RAM).

Computing device 1000 may include a heat regulation/refrigeration device 1006. Heat regulation/refrigeration device 1006 may maintain processing device 1001 (and/or other components of computing device 1000) at a predetermined low temperature during operation. This predetermined low temperature may be any temperature discussed elsewhere herein.

In some embodiments, computing device 1000 may include a communication chip 1007 (e.g., one or more communication chips). For example, the communication chip 1007 may be configured for managing wireless communications for the transfer of data to and from computing device 1000. The term “wireless” and its derivatives may be used to describe circuits, devices, systems, methods, techniques, communications channels, etc., that may communicate data through the use of modulated electromagnetic radiation through a nonsolid medium.

Communication chip 1007 may implement any wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1007 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1007 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1007 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1007 may operate in accordance with other wireless protocols in other embodiments. Computing device 1000 may include an antenna 1013 to facilitate wireless communications and/or to receive other wireless communications (such as AM or FM radio transmissions).

In some embodiments, communication chip 1007 may manage wired communications, such as electrical, optical, or any other suitable communication protocols (e.g., the Ethernet). As noted above, communication chip 1007 may include multiple communication chips. For instance, a first communication chip 1007 may be dedicated to shorter-range wireless communications such as Wi-Fi or Bluetooth, and a second communication chip 1007 may be dedicated to longer-range wireless communications such as GPS, EDGE, GPRS, CDMA, WiMAX, LTE, EV-DO, or others. In some embodiments, a first communication chip 1007 may be dedicated to wireless communications, and a second communication chip 1007 may be dedicated to wired communications.

Computing device 1000 may include battery/power circuitry 1008. Battery/power circuitry 1008 may include one or more energy storage devices (e.g., batteries or capacitors) and/or circuitry for coupling components of computing device 1000 to an energy source separate from computing device 1000 (e.g., AC line power).

Computing device 1000 may include a display device 1003 (or corresponding interface circuitry, as discussed above). Display device 1003 may include any visual indicators, such as a heads-up display, a computer monitor, a projector, a touchscreen display, a liquid crystal display (LCD), a light-emitting diode display, or a flat panel display, for example.

Computing device 1000 may include an audio output device 1004 (or corresponding interface circuitry, as discussed above). Audio output device 1004 may include any device that generates an audible indicator, such as speakers, headsets, or earbuds, for example.

Computing device 1000 may include an audio input device 1010 (or corresponding interface circuitry, as discussed above). Audio input device 1010 may include any device that generates a signal representative of a sound, such as microphones, microphone arrays, or digital instruments (e.g., instruments having a musical instrument digital interface (MIDI) output).

Computing device 1000 may include a global positioning system (GPS) device 1009 (or corresponding interface circuitry, as discussed above). GPS device 1009 may be in communication with a satellite-based system and may receive a location of computing device 1000, as known in the art.

Computing device 1000 may include another output device 1005 (or corresponding interface circuitry, as discussed above). Examples include an audio codec, a video codec, a printer, a wired or wireless transmitter for providing information to other devices, or an additional storage device.

Computing device 1000 may include another input device 1011 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1000 may include a security interface device 1012. Security interface device 1012 may include any device that provides security measures for computing device 1000 such as intrusion detection, biometric validation, security encode or decode, managing access lists, malware detection, or spyware detection.

Computing device 1000, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the disclosure is not limited to the embodiments so described but can be practiced with modification and alteration without departing from the scope of the appended claims. For example, the above embodiments may include specific combinations of features as further provided below.

In first examples, an apparatus comprises a substrate comprising glass, a plurality of through holes extending through the glass, a via metallization within the through holes, and a buffer within the through holes. The buffer is between the via metallization and the glass. The buffer comprises an inorganic material having an elastic modulus of less than 110 GPa.

In second examples, for any of the first examples the elastic modulus is less than 100 GPa.

In third examples, for any of the first through second examples the inorganic material has a thermal expansion coefficient (CTE) of less than 25 ppm/K.

In fourth examples, for any of the third examples the elastic modulus is less than 90 GPa and the CTE is at least 9 ppm/K.

In fifth examples, for any of the first through fourth examples the inorganic material comprises at least one of a metal, silicon, nitrogen, or carbon.

In sixth examples, for any of the fifth example the inorganic material comprises predominantly one of Al, Sn, or Sc.

In seventh examples for any of the fifth through sixth examples the inorganic material comprises an alloy of two or more metals.

In eighth examples, for any of the seventh examples the two or more metals comprises at least two of Al, Sn, Sc, In, or Ti.

In ninth examples, for any of the first through fifth examples the inorganic material comprises a metal carbide or a metal silicide.

In tenth examples, for any of the first through ninth examples the buffer has a minimum thickness of 50 nm.

In eleventh examples, for any of the first through tenth examples the buffer is one of a plurality of material layers between the glass and the via metallization.

In twelfth examples, for any of the eleventh examples the via metallization comprises Cu and wherein the plurality of layers comprises a material layer between the buffer and the glass or between the buffer and the via metallization.

In thirteenth examples, a system comprises a plurality of integrated circuit (IC) die electrically coupled to first metallization features on a first side of a substrate comprising glass. A plurality of through holes extends through the glass. A metallization within the through holes, the metallization electrically coupling the first metallization features to second metallization features on a second side of the glass. An inorganic material is within the holes and between the metallization and the glass. The inorganic material comprises at least one of Al, Sn, or Sc.

In fourteenth examples, for any of the thirteenth example the inorganic material is absent from the first metallization features.

In fifteenth examples for any of the thirteenth through fourteenth examples the system further comprises an electrical routing structure on the first side of the glass. The routing structure comprises the first metallization features and an organic dielectric material. The plurality of through vias extend from the routing structure to a second side of the glass. The routing structure electrically couples the through vias to at least one of the plurality of IC die.

In sixteenth examples, for any of the fifteenth example each of the plurality of IC die is coupled to the routing structure either through a direct bond or through solder features.

In seventeenth examples, for any of the thirteenth through sixteenth examples the inorganic material has an elastic modulus less than 90 GPa and the CTE is at least 9 ppm/K.

In eighteenth examples a method comprises receiving a workpiece comprising glass, forming holes through the glass, depositing a buffer upon a sidewall of the holes and over a surface of the glass between the through holes. The buffer comprises an inorganic material with an elastic modulus of less than 110 GPa, and the method comprises forming metallization within the holes and over the buffer and forming conductive through vias by planarizing the metallization and the buffer with the surface of the glass.

In nineteenth examples, for any of the eighteenth examples the method comprises building up, over the surface of the glass, an electrical routing structure coupled to the through vias, and attaching an IC die to the electrical routing structure.

In twentieth examples, for any of the eighteenth through nineteenth examples the method comprises depositing the buffer further comprises sputter depositing an inorganic material comprising at least of a metal, silicon, nitrogen, or carbon.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosure should therefore be determined with reference to the appended claims, along with the full scope of equivalents to which such claims are entitled.

What is claimed is:

1. An apparatus, comprising:
a substrate comprising glass;
a plurality of holes extending through the glass;
a via metallization within the holes; and
a buffer within the holes, wherein:
the buffer is between the via metallization and the glass; and
the buffer comprises an inorganic material having an elastic modulus of less than 110 GPa.

2. The apparatus of claim 1, wherein the elastic modulus is less than 100 GPa.

3. The apparatus of claim 1, wherein the inorganic material has a thermal expansion coefficient (CTE) of less than 25 ppm/K.

4. The apparatus of claim 3, wherein the elastic modulus is less than 90 GPa and the CTE is at least 9 ppm/K.

5. The apparatus of claim 1, wherein the inorganic material comprises at least one of a metal, silicon, nitrogen, or carbon.

6. The apparatus of claim 5, wherein the inorganic material comprises predominantly one of Al, Sn, or Sc.

7. The apparatus of claim 5, wherein the inorganic material comprises an alloy of two or more metals.

8. The apparatus of claim 7, wherein the two or more metals comprises at least two of Al, Sn, Sc, In, or Ti.

9. The apparatus of claim 5, wherein the inorganic material comprises a metal carbide or a metal silicide.

10. The apparatus of claim 1, wherein the buffer has a minimum thickness of 50 nm.

11. The apparatus of claim 10, wherein the buffer is one of a plurality of material layers between the glass and the via metallization.

12. The apparatus of claim 11, wherein the via metallization comprises Cu and wherein the plurality of layers comprises a material layer between the buffer and the glass or between the buffer and the via metallization.

13. A system comprising:
a plurality of integrated circuit (IC) die electrically coupled to first metallization features on a first side of a substrate comprising glass;
a plurality of holes extending through the glass;
a metallization within the holes, the metallization electrically coupling the first metallization features to second metallization features on a second side of the glass; and
an inorganic material within the holes and between the metallization and the glass, wherein the inorganic material comprises at least one of Al, Sn, or Sc.

14. The system of claim 13, wherein the inorganic material is absent from the first metallization features.

15. The system of claim 13, further comprising an electrical routing structure on the first side of the glass, the routing structure comprising the first metallization features and an organic dielectric material, and wherein the plurality of through vias extend from the routing structure to a second side of the glass, and wherein the routing structure electrically couples the through vias to at least one of the plurality of IC die.

16. The system of claim 15, wherein each of the plurality of IC die is coupled to the routing structure either through a direct bond or through solder features.

17. The system of claim 13, wherein the inorganic material has an elastic modulus less than 90 GPa and a coefficient of thermal expansion of at least 9 ppm/K.

18. A method comprising:
receiving a workpiece comprising glass;
forming holes through the glass;
depositing a buffer upon a sidewall of the holes and over a surface of the glass between the through holes, wherein the buffer comprises an inorganic material with an elastic modulus of less than 110 GPa;
forming metallization within the holes and over the buffer; and
forming conductive through vias by planarizing the metallization and the buffer with the surface of the glass.

19. The method of claim 18 further comprising:
building up, over the surface of the glass, an electrical routing structure coupled to the through vias; and
attaching an IC die to the electrical routing structure.

20. The method of claim 18, wherein depositing the buffer further comprises sputter depositing an inorganic material comprising at least of a metal, silicon, nitrogen, or carbon.
